(19) United States
(12) Patent Application Publication
(10) Pub. No.: US 2023/0291386 A1
(43) Pub. Date: Sep. 14, 2023

(54) HIGH-FREQUENCY CIRCUIT AND FILTER CIRCUIT

(71) Applicant: Kimiyuki OBA, Tokyo (JP)

(72) Inventor: Kimiyuki OBA, Tokyo (JP)

(73) Assignee: MITSUMI ELECTRIC CO., LTD., Tokyo (JP)

(21) Appl. No.: 18/167,965

(22) Filed: Feb. 13, 2023

(30) Foreign Application Priority Data
Mar. 9, 2022 (JP) 2022-036075

(51) Int. Cl. H03H 9/56; H03H 9/205

(52) U.S. Cl. CPC H03H 9/568; H03H 9/205; H03H 9/133

(57) ABSTRACT

A high-frequency circuit includes a signal wire connecting a pair of signal terminals; and a reference potential wire arranged along and close to the signal wire and connecting a pair of reference potential terminals.

### CROSS-REFERENCE TO RELATED APPLICATIONS

The present application is based upon and claims priority under 35 U.S.C. §119 to Japanese Patent Application No. 2022-036075 filed on Mar. 9, 2022, the entire contents of which are incorporated herein by reference.

### BACKGROUND OF THE INVENTION

### 1. Field of the Invention

The present disclosure relates to a high-frequency circuit and a filter circuit.

### 2. Description of the Related Art

Conventionally, among high-frequency circuits in which a line configured with a center conductor and a ground conductor formed on a board has another line connected at the end, there has been a high-frequency circuit in which a filter is formed at the end by changing the line impedance by partially deforming the shape of at least one of the center conductor and the ground conductor, to match the impedance between an input end and an output end of the filter (e.g., see Patent Document 1).

### [Related Art Documents]

### [Patent Documents]

[Patent Document 1] Japanese Laid-Open Patent Application No. 2001-102820

Meanwhile, such a conventional high-frequency circuit has a filter provided on part of the line in order to match the impedance, and hence, the circuit configuration is not simple.

### SUMMARY OF THE INVENTION

A high-frequency circuit according to an embodiment in the present disclosure includes a signal wire to connect a pair of signal terminals, and a reference potential wire arranged along and close to the signal wire to connect a pair of reference potential terminals.

### BRIEF DESCRIPTION OF THE DRAWINGS

FIG. 1 is a diagram illustrating an example of a configuration of a filter circuit 100 that includes high-frequency circuits 50A and 50B according to an embodiment;

FIG. 2A is a diagram illustrating an example of a configuration of an FBAR 20A;

FIG. 2B is a diagram illustrating an example of a configuration of an SMR 20B;

FIG. 3A is a diagram illustrating a simulation model of a filter circuit 30A for comparison;

FIG. 3B is a diagram illustrating a frequency characteristic of an S11 parameter (reflection coefficient) in the filter circuit 30A for comparison;

FIG. 4A is a diagram illustrating a simulation model of a filter circuit 30B for comparison;

FIG. 4B is a diagram illustrating a frequency characteristic of an S11 parameter in the filter circuit 30B for comparison;

FIG. 5A is a diagram illustrating a simulation model of the filter circuit 100 according to an embodiment;

FIG. 5B is a diagram illustrating a frequency characteristic of an S11 parameter in the filter circuit 100 according to an embodiment;

FIG. 6 is a diagram illustrating a simulation model of the filter circuit 40A for comparison;

FIGS. 7A and 7B are diagrams illustrating simulation results of an S parameter for the filter circuit 40A for comparison;

FIG. 8 is a diagram illustrating a simulation model of the filter circuit 40B for comparison;

FIGS. 9A and 9B are diagrams illustrating simulation results of an S parameter for the filter circuit 40B for comparison;

FIG. 10 is a diagram illustrating a simulation model of a filter circuit 200 according to an embodiment;

FIGS. 11A and 11B are diagrams illustrating simulation results of an S parameter for the filter circuit 200 according to an embodiment; and

FIG. 12 is a diagram illustrating an IC package 300 to which a high-frequency circuit 50M of a modified example of an embodiment is applied.

### DESCRIPTION OF THE PREFERRED EMBODIMENTS

In the following, embodiments will be described to which a high-frequency circuit and a filter circuit according to the present disclosure are applied.

According to an embodiment, a high-frequency circuit and a filter circuit in which the impedance can be matched with a simple circuit configuration can be provided.

### Embodiments

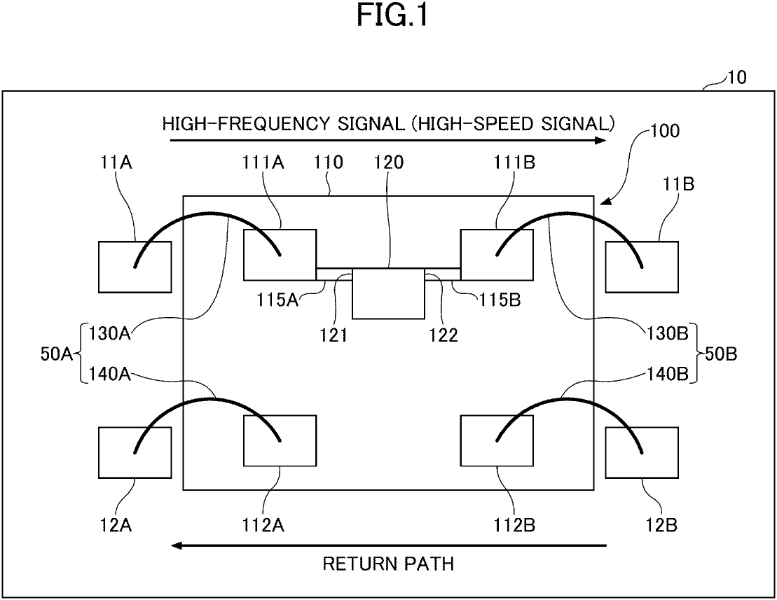

FIG. 1 is a diagram illustrating an example of a configuration of a filter circuit 100 that includes high-frequency circuits 50A and 50B according to an embodiment. The filter circuit 100 is a BPF (bandpass filter) that includes a board 110, a resonator 120, bonding wires 130A and 130B, and bonding wires 140A and 140B. The filter circuit 100 is mounted on the upper surface of the board 10.

The board 10 is a circuit board compliant with FR-4 (Flame Retardant type 4) standards or the like. The board 10 include signal terminals 11A and 11B and ground terminals 12A and 12B. The signal terminals 11A and 11B and the ground terminals 12A and 12B are provided on the upper surface of the board 10.

The signal terminal 11A is connected to, as an example, a signal output part or the like (not illustrated), into which a high-frequency signal is input. In addition, the signal terminal 11B is connected to, as an example, a circuit or the like that processes high-frequency signals. The high-frequency signal is, as an example, an analog signal belonging to a frequency band such as a millimeter-wave band from 30 GHz to 300 GHz, a quasi-millimeter-wave band from 24 GHz to 30 GHz, or a Sub-6 band lower than 6 GHz, but not limited to signals in these frequency bands.

The ground terminals 12A and 12B are held at a ground potential (0 V). Points held at a reference potential such as the ground terminals 12A and 12B are examples of a reference potential point. The ground potential is an example of a reference potential. Here, as an example, a configuration in which the reference potential is the ground potential will be described; however, the reference potential may be a fixed potential offset from the ground potential.

Signal wires 115A and 115B connected to terminals 121 and 122 of the resonator 120 of the filter circuit 100 are connected between the signal terminals 11A and 11B via bonding wires 130A and 130B; and ground potential wires (ground wires) of the board 110 of the filter circuit 100 are connected between the ground terminals 12A and 12B via bonding wires 140A and 140B. Therefore, a high-frequency signal (high-speed signal) is propagated from the signal terminal 11A to the signal terminal 11B, and a path from the ground terminal 12B to the ground terminal 12A serves as a return path. Note that the terminal 121 is an example of a first terminal, and the terminal 122 is an example of a second terminal. In addition, the signal wires 115A and 115B are microstrip lines, as an example. In FIG. 1, although the signal wires 115A and 115B are illustrated on the upper surface of the board 110, these wires may be provided in an inner layer or on the lower surface of the board 110.

The bonding wires 130A and 140A construct the high-frequency circuit 50A according to the embodiment, and the bonding wires 130B and 140B construct the high-frequency circuit 50B according to the embodiment. The configuration of the high-frequency circuits 50A and 50B will be described later.

The bonding wires 130A and 130B are bonding wires to transmit analog signals. The bonding wire 130A is an example of a signal wire as well as an example of a first signal wire. The bonding wire 130B is an example of a signal wire as well as an example of a second signal wire. The signal terminal 11A of the board 10 and a signal terminal 111A of the board 110, which are connected to both ends of the bonding wire 130A, are examples of a pair of signal terminals. In addition, the signal terminal 111A of the board 110, which is connected to one end of the bonding wire 130A, is an example of a first signal terminal. Similarly, the signal terminal 11B of the board 10 and a signal terminal 111B of the board 110, which are connected to both ends of the bonding wire 130B, are examples of a pair of signal terminals. The signal terminal 111B of the board 110, which is connected to one end of the bonding wire 130B, is an example of a second signal terminal.

The bonding wires 140A and 140B are bonding wires connected to the ground terminals 12A and 12B, to be held at the ground potential. The bonding wire 140A is an example of a reference potential wire. Similarly, the bonding wire 140B is an example of a reference potential wire. The ground terminal 12A of the board 10 and a ground terminal 112A of the board 110, which are connected to both ends of the bonding wire 140A, are examples of a pair of reference potential terminals. Similarly, the ground terminal 12B of the board 10 and a ground terminal 112B of the board 110, which are connected to both ends of the bonding wire 140B, are examples of a pair of reference potential terminals.

In addition, the bonding wires 140A and 140B are examples of a first reference potential wire. In addition, the bonding wire 140A is an example of a first portion of a first reference potential wire, and the bonding wire 140B is an example of a second portion of a first reference potential wire. Note that one bonding wire may be used instead of being divided into two as in the case of the bonding wires 140A and 140B.

The board 110 is, for example, a circuit board compliant with FR-4 standards or the like. The board 110 is arranged on the upper surface of the board 10. The board 110 includes the signal terminals 111A and 111B, the ground terminals 112A and 112B, and the signal wires 115A and 115B. The signal wires 115A and 115B are connected to the signal terminals 111A and 111B, respectively. The signal terminals 111A and 111B and the ground terminals 112A and 112B are provided on the upper surface of the board 110, and made of metal such as copper foil. In addition, the resonator 120 is mounted on the upper surface of the board 110. The ground terminals 112A and 112B are connected by a ground wire provided on the upper surface, in an inner layer, or on the lower surface of the board 110.

As an example, the resonator 120 is a device that can be used as a filter having a passband of a predetermined frequency band by using a resonance characteristic. In other words, the resonator 120 has a filter characteristic. As the resonator 120 as such, for example, a BAW (Bulk Acoustic Wave) filter can be used. The resonator 120 has the terminal 121 and the terminal 122. The resonator 120 is an example of a first resonator.

The resonator 120 is surrounded by the signal terminals 111A and 111B and the ground terminals 112A and 112B in plan view, and the terminals 121 and 122 of the resonator 120 are connected to the signal terminals 111A and 111B via the signal wires 115A and 115B.

Therefore, a high-frequency signal is input from the signal terminal 11A of the board 10 to the resonator 120 via the bonding wire 130A, the signal terminal 111A, and the signal wire 115A. The resonator 120 passes components in a predetermined frequency band, among high-frequency signals that are input, and a high-frequency signal passed through the resonator 120 is transmitted to the signal terminal 11B of the board 10 via the signal wire 115B, the signal terminal 111B, and the bonding wire 130B. At this time, a path from the ground terminal 12B to the ground terminal 12A via the bonding wire 140B, the ground terminal 112B, the ground wire of the board 110, the ground terminal 112A, and the bonding wire 140A serves as a return path.

Note that the bonding wires 130A and 130B and the bonding wires 140A and 140B are, for example, wires made of metal such as gold, silver, copper, or aluminum.

As described above, the bonding wires 130A and 140A construct the high-frequency circuit 50A, and the bonding wires 130B and 140B construct the high-frequency circuit 50B. The high-frequency circuits 50A and 50B are circuits in which the bonding wires 140A and 140B at the ground potential are arranged along and close to the signal bonding wires 130A and 130B, respectively, in order to match the characteristic impedance of the signal bonding wires 130A and 130B with a target value of 50 Ω.

Here, matching the characteristic impedance with 50 Ω means that, in addition to matching the characteristic impedance with 50 Ω, causing the characteristic impedance to be closer to 50 Ω so as to obtain a good transmission characteristic of a signal. In addition, arranging the ground potential bonding wire 140A along and close to the signal bonding wire 130A means that sufficient capacitive coupling of the bonding wires 130A and 140A is generated in an interval from one end to the other end of the bonding wire 130A, such that the bonding wire 140A is arranged along the bonding wire 130A; and the capacitive coupling of the bonding wires 130A and 140A improves the characteristic impedance of the bonding wire 130A so as to approach the target value. Note that the same applies to the bonding wires 130B and 140B.

In the following, the high-frequency circuits 50A and 50B having such a characteristic impedance will be referred to as the high-frequency circuits 50A and 50B in which the impedance is matched. Note that although a form in which the target value of the characteristic impedance is 50 Ω will be described, a resistance value other than 50 Ω may be adopted.

In general, in order to match the characteristic impedance of signal wires with 50 Ω, a microstrip line, a coplanar wave guide, or the like are formed on a circuit board. However, in the case where, for some reason, it is not possible to connect a device such as the filter circuit 100 with another device such as a microstrip line or a coplanar wave guide formed on the circuit board, a bonding wire may be used. Therefore, in FIG. 1, the bonding wires 130A and 130B are used for signals.

Meanwhile, if a high-frequency signal is transmitted only by bonding wires for signals, the impedance is not matched due to inductance components, resistance components, and the like of the bonding wires, and the transmission characteristic of the signal is degraded. In addition, in the case where a return path is not present, concerns may arise such as an occurrence of a portion where the characteristic impedance becomes significantly discontinuous, and an occurrence of further signal degradation.

Because of these reasons, the filter circuit 100 uses the high-frequency circuits 50A and 50B that are configured with the bonding wires 130A and 140A and the bonding wires 130B and 140B, in which the impedance is matched. In the following, an outline of a BAW filter used as the resonator 120 and simulation results using the high-frequency circuits 50A and 50B will be described.

### Outline of BAW Filter

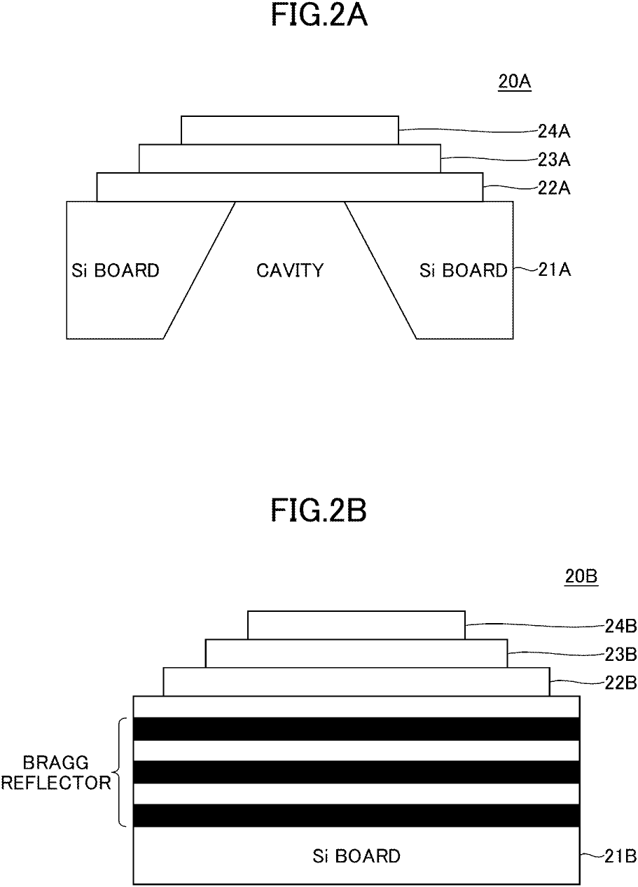

FIG. 2A is a diagram illustrating an example of a configuration of an FBAR (Film Bulk Acoustic Resonator) 20A. The FBAR filter 20A is an example of a BAW filter. The FBAR filter 20A has a configuration in which a lower electrode 22A, a piezoelectric thin film 23A, and an upper electrode 24A are stacked to be arranged on a silicon (Si) substrate 21A having a cavity. The silicon substrate 21A having the cavity is, for example, a MEMS (Micro Electro Mechanical Systems) element. The piezoelectric thin film 23A is a piezo element or the like made of aluminum nitride (AlN) or zinc oxide (ZnO).

In the FBAR filter 20A as such, when a high-frequency signal is applied between the lower electrode 22A and the upper electrode 24A, the piezoelectric thin film 23A vibrates between the lower electrode 22A and the upper electrode 24A, to generate a standing wave in a lateral direction in FIG. 2A. The vibration characteristic of this standing wave can be used as a pass band of the filter of the resonator 120.

FIG. 2B is a diagram illustrating an example of a configuration of an SMR (Solid Mounted Resonator) 20B. The SMR filter 20B is an example of a BAW filter. The SMR filter 20B has a configuration in which a lower electrode 22B, a piezoelectric thin film 23B, and an upper electrode 24B are stacked to be arranged on a silicon (Si) substrate 21B having a Bragg reflector. The silicon substrate 21B having a Bragg reflector is, for example, a MEMS element. The piezoelectric thin film 23B is a piezo element or the like made of aluminum nitride (AlN) or zinc oxide (ZnO).

In the SMR filter 20B as such, when a high-frequency signal is applied between the lower electrode 22B and the upper electrode 24B, vibration of the piezoelectric thin film 23B is transmitted to the Bragg reflector, to generate a standing wave. The vibration characteristic of this standing wave can be used as a pass band of the filter of the resonator 120.

### Simulation

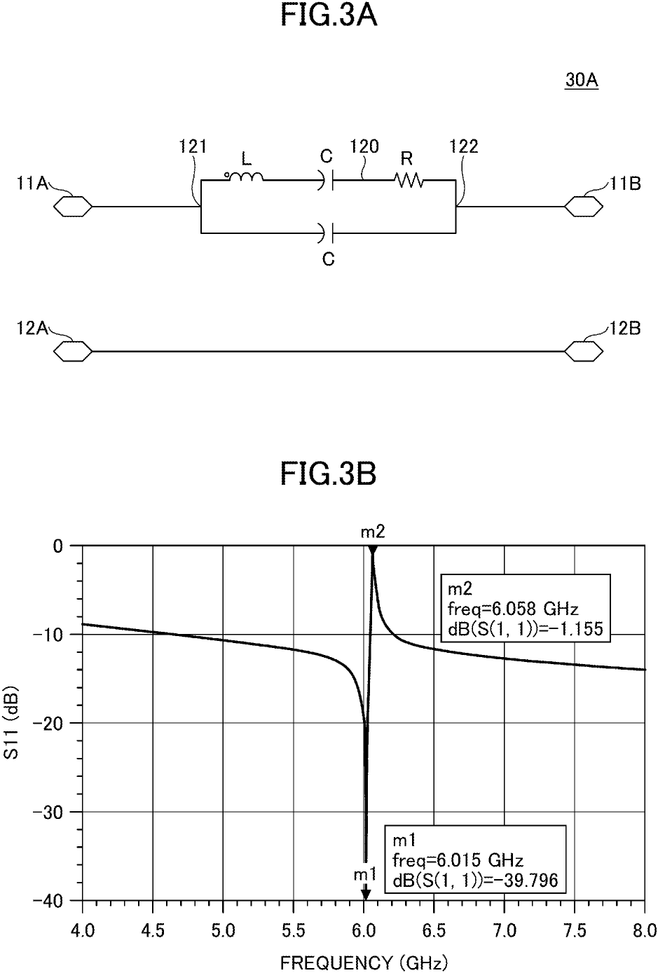

FIG. 3A is a diagram illustrating a simulation model of a filter circuit 30A for comparison. The filter circuit 30A for comparison is a BPF that includes signal terminals 11A and 11B, ground terminals 12A and 12B, and a resonator 120. The signal terminals 11A and 11B, the ground terminals 12A and 12B, and the resonator 120 are substantially the same as those illustrated in FIG. 1. In FIG. 3A, the resonator 120 is illustrated as an equivalent circuit in which a series circuit of an inductor L, a capacitor C, and a resistor R, having another capacitor C connected in parallel.

The filter circuit 30A for comparison does not include a bonding wire, and the signal terminals 11A and 11B, and the terminals 121 and 122 of the resonator 120 are connected by microstrip lines. In this way, in the filter circuit 30A for comparison, a signal transmission path between the signal terminals 11A and 11B is implemented with a line of an ideal characteristic impedance.

FIG. 3B is a diagram illustrating a frequency characteristic of an S11 parameter (reflection coefficient) in the filter circuit 30A for comparison. In FIG. 3B, the horizontal axis represents the frequency (GHz) and the vertical axis represents the S11 parameter (dB). Note that the resonant frequency of the resonator 120 was set to 6.015 GHz. The S11 parameter is a ratio of reflected power to input power at the signal terminal 11A serving as the input terminal of the high-frequency signal.

As illustrated in FIG. 3B, a resonance point m1 was obtained at 6.015 GHz, and the S11 parameter was -39.8 dB. An anti-resonance point m2 was obtained at 6.058 GHz, and the S11 parameter was -1.2 dB. It could be confirmed that the filter circuit 30A for comparison that includes a signal transmission line having an ideal characteristic impedance had the S11 parameter at the resonance point being very low, and that resonance with low reflection and a high Q value was obtained.

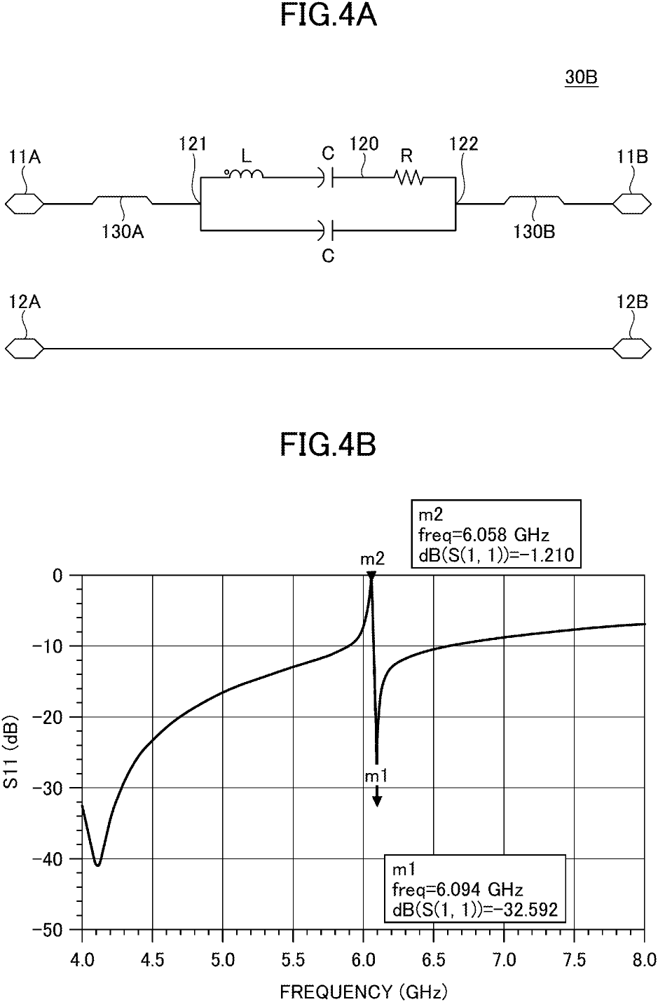

FIG. 4A is a diagram illustrating a simulation model of a filter circuit 30B for comparison. The filter circuit 30B for comparison is a BPF that includes signal terminals 11A and 11B, ground terminals 12A and 12B, bonding wires 130A and 130B, and a resonator 120. The signal terminals 11A and 11B, the ground terminals 12A and 12B, and the resonator 120 are substantially the same as those illustrated in FIG. 1. Note that the signal wires 115A and 115B of the board 110 connecting the terminals 121 and 122 of the resonator 120 with the signal terminals 111A and 111B are omitted here because these wires are very short compared to the bonding wires 130A and 130B.

In the filter circuit 30B for comparison, only the bonding wires 130A and 130B for signals are connected between the signal terminals 11A and 11B and the terminals 121 and 122 of the resonator 120, and the bonding wires 140A and 140B for ground illustrated in FIG. 1 are not provided; therefore, no improvement is made to the characteristic impedance of the bonding wires 130A and 130B. Therefore, between the signal terminals 11A and 11B, and the terminals 121 and 122 of the resonator 120, the characteristic impedance would be significantly deviated from 50 Ω, and the high-frequency signal would propagate in the signal transmission path where the impedance is not matched. In addition, a return path is formed between the ground terminals 12A and 12B by connection formed with wires of a circuit board.

FIG. 4B is a diagram illustrating a frequency characteristic of an S11 parameter (reflection coefficient) in the filter circuit 30B for comparison. As illustrated in FIG. 4B, a resonance point m1 was obtained at 6.094 GHz, and the S11 parameter was -32.592 dB. An anti-resonance point m2 was obtained at 6.058 GHz, and the S11 parameter was -1.2 dB. Compared to the filter circuit 30A for comparison that includes a signal transmission line of an ideal characteristic impedance, it could be confirmed that the filter circuit 30B for comparison had the resonance frequency deviated, and that the S11 parameter at the resonance point became higher by approximately 10 dB. It could be confirmed that the S11 parameter at 6.015 GHz as the resonance frequency of the filter circuit 30A for comparison, was approximately -6 dB, and the reflection increased greatly. In this way, it could be confirmed that the transmission characteristic of a signal was degraded when the impedance of the signal transmission line was not matched.

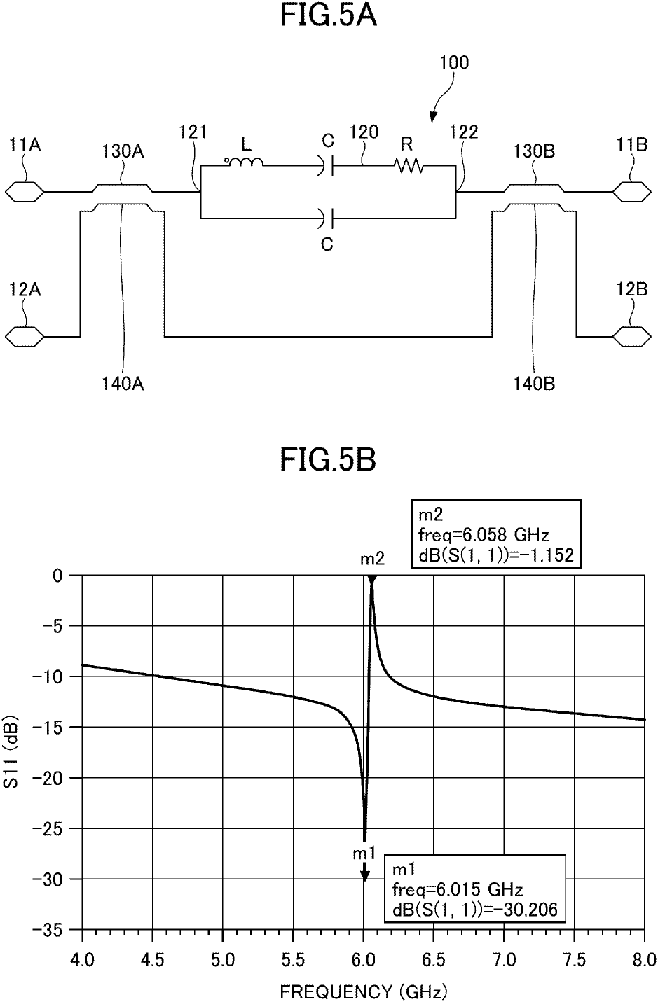

FIG. 5A is a diagram illustrating a simulation model of the filter circuit 100 according to the embodiment. The signal wires 115A and 115B of the board 110 connecting the terminals 121 and 122 of the resonator 120 with the signal terminals 111A and 111B are omitted here because these wires are very short compared to the bonding wires 130A and 130B.

In the filter circuit 100 according to the embodiment, the signal terminals 11A and 11B and the terminals 121 and 122 of the resonator 120 are connected by the bonding wires 130A and 130B for signals, and the bonding wires 140A and 140B are provided along and close to the bonding wires 130A and 130B; therefore, in the signal transmission path between the signal terminals 11A and 11B and the terminals 121 and 122 of the resonator 120, the impedance is matched. In addition, a return path is formed between the ground terminals 12A and 12B by being connected by the bonding wires 140A and 140B.

FIG. 5B is a diagram illustrating a frequency characteristic of an S11 parameter (reflection coefficient) in the filter circuit 100 according to the embodiment. As illustrated in FIG. 5B, a resonance point m1 was obtained at 6.015 GHz, and the S11 parameter was -30.206 dB. An anti-resonance point m2 was obtained at 6.058 GHz, and the S11 parameter was -1.2 dB. The resonant frequency of the filter circuit 100 according to the embodiment was coincident with that of the filter circuit 30A for comparison that includes a signal transmission path of an ideal characteristic impedance. It could be confirmed that although the S11 parameter at the resonant point became approximately 10 dB higher, it took a sufficiently low value. It could be confirmed that a good transmission characteristic of a signal could be obtained as long as the impedance of the bonding wires 130A and 130B was matched.

### Simulation with Ladder-Type Filter Circuit

### Simulation Model of Filter Circuit 40A for Comparison

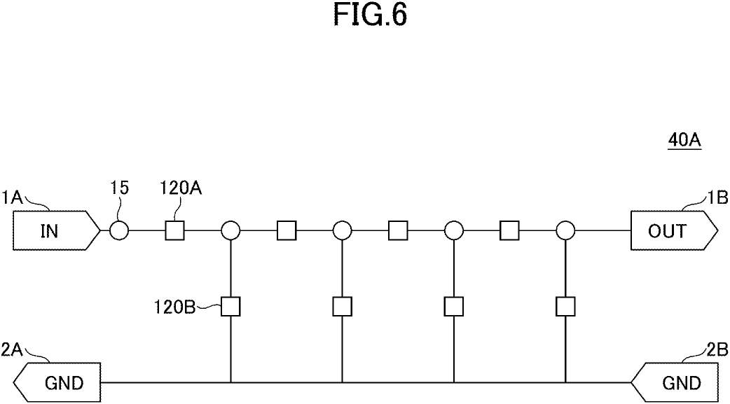

FIG. 6 is a diagram illustrating a simulation model of a filter circuit 40A for comparison. The filter circuit 40A for comparison is a BPF that includes a signal input terminal 1A, a signal output terminal 1B, a ground terminal 2A, a ground terminal 2B, signal wires 15, resonators 120A, and resonators 120B, and is mounted on a board that is similar to the board 10 illustrated in FIG. 1. The passband of the resonator 120A is higher than that of the resonator 120B. The resonator 120A is an example of a first resonator, and the resonator 120B is an example of a second resonator. The passband of the resonator 120A is an example of a first passband, and the passband of the resonator 120B is an example of a second passband. This configuration is adopted to have the resonators 120A specify the upper limit frequency of the passband of the filter circuit 40A as the BPF, and have the resonators 120B specify the lower limit frequency of the passband of the filter circuit 40A as the BPF. A line connecting between the ground terminals 2A and 2B is a ground wire held at the ground potential.

The signal input terminal 1A is connected to, as an example, a signal output part or the like (not illustrated), into which a high-frequency signal is input. In addition, as an example, the signal output terminal 1B is connected to a circuit or the like that processes high-frequency signals, from which a high-frequency signal passed through the passband of the filter circuit 40A is output.

The signal wires 15 are signal wires included in a board that is similar to the board 10 illustrated in FIG. 1, and five signal wires 15 are illustrated in FIG. 6. There are four resonators 120A and four resonators 120B, all configured as BAW filters. The resonant frequency of the resonator 120A is set to be higher than that of the resonator 120B.

The four resonators 120A and the four resonators 120B are connected in a ladder shape among the signal input terminal 1A, the signal output terminal 1B, the ground terminal 2A, and the ground terminal 2B. More specifically, the five signal wires 15 are connected between the signal input terminal 1A and the signal output terminal 1B, and the four resonators 120A are connected between the five signal wires 15. Each of the four resonators 120B is inserted in series into a corresponding one of four branch lines between four signal wires 15 positioned downstream of the respective four resonators 120A in the signal transmission direction (from the signal input terminal 1A to the signal output terminal 1B), and the ground wire. The four resonators 120A are series arms and the four resonators 120B are parallel arms.

The filter circuit 40A for comparison, like the filter circuit 30A for comparison illustrated in FIG. 3A, does not include any bonding wires; and the signal input terminal 1A, the signal output terminal 1B, the ground terminal 2A, the ground terminal 2B, the resonators 120A, and the resonators 120B are connected by the signal wires 15 on the board, to be implemented with a line of an ideal characteristic impedance.

### Simulation Results of Filter Circuit 40A for Comparison

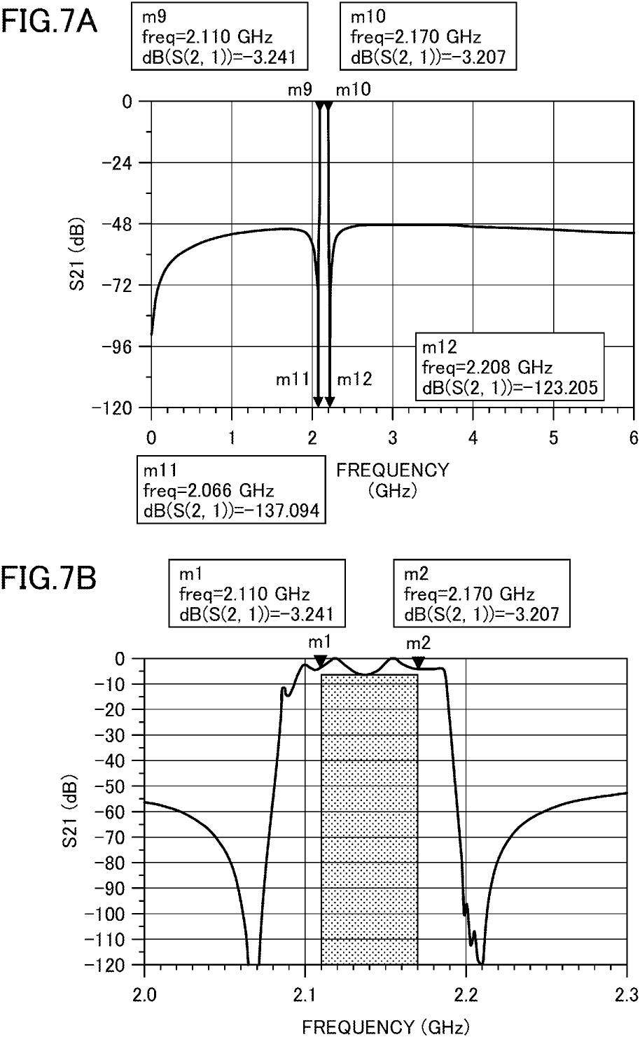

FIGS. 7A and 7B are diagrams illustrating simulation results of an S parameter for a filter circuit 40A for comparison. FIGS. 7A and 7B illustrate an S21 parameter (passing characteristic). FIG. 7B is a diagram illustrating an enlarged view of FIG. 7A in the horizontal (frequency) direction. The S21 parameter represents a ratio of the power of a high-frequency signal output from the signal output terminal 1B to the power of the high-frequency signal input into the signal input terminal 1A.

As illustrated in FIGS. 7A and 7B, m9 (FIG. 7A) and m1 (FIG. 7B) as the lower limit frequency of the passband were 2.110 GHz, and the S21 parameter was -3.241 dB. In addition, m10 (FIG. 7A) and m2 (FIG. 7B) as the upper limit frequency of the passband were 2.170 GHz, and the S21 parameter was -3.207 dB.

A region in gray in FIG. 7B, being less than or equal to approximately -2.5 dB between 2.110 GHz and 2.170 GHz illustrated, is a region where it is desired to be secured as a pass-through characteristic. As illustrated in FIG. 7B, as for the characteristic of the S21 parameter, only a small part enters the gray region, and it could be confirmed that a good pass-through characteristic was obtained. In addition, in a band where the frequency is lower than 2.110 GHz as the lower limit frequency of the pass-band, and in a band where the frequency is higher than 2.170 GHz as the upper limit frequency, the S21 parameter was less than or equal to -48 dB as illustrated in FIG. 7A, and it could be confirmed that a good cutoff characteristic was obtained.

### Simulation Model of Filter Circuit 40B for Comparison

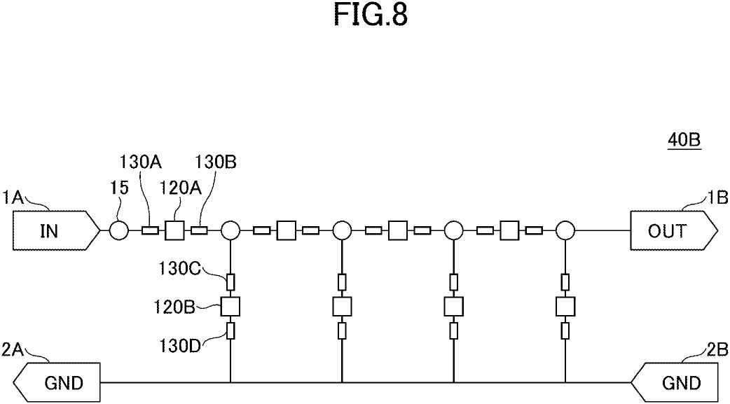

FIG. 8 is a diagram illustrating a simulation model of a filter circuit 40B for comparison. The filter circuit 40B for comparison is a BPF that includes a signal input terminal 1A, a signal output terminal 1B, a ground terminal 2A, a ground terminal 2B, signal wires 15, resonators 120A, resonators 120B, and bonding wires 130A, 130B, 130C, and 130D; and is mounted on a board that is similar to the board 10 illustrated in FIG. 1. Here, for elements that are substantially the same as those of the filter circuit 40A illustrated in FIG. 6, the same reference numerals are assigned, and the description is omitted.

The bonding wires 130A and 130B are connected to both sides of each of the resonators 120A, and correspond to the bonding wires 130A and 130B on both sides of the resonator 120 in the filter circuit 30B for comparison illustrated in FIG. 4A. Here, as in FIG. 4A, the signal wires 115A and 115B of the board 110 connecting the resonator 120 and the signal terminals 111A and 111B in FIG. 1 are omitted.

In the filter circuit 40B for comparison illustrated in FIG. 8, like the bonding wires 130A and 130B in the filter circuit 30B for comparison illustrated in FIG. 4A, the bonding wires 140A and 140B for ground illustrated in FIG. 1 are not provided for the bonding wires 130A and 130B; therefore, a high-frequency signal propagates in a signal transmission path in which the impedance is not matched.

In addition, the ends of the bonding wires 130A and 130B opposite to those connected to the resonator 120A are connected to the signal wires 15 via signal terminals corresponding to the signal terminals 11A and 11B illustrated in FIG. 1.

In addition, the bonding wires 130C and 130D are connected to both sides of the resonators 120B, as are the bonding wires 130A and 130B on both sides of the resonators 120A. Here, the signal wire corresponding to the signal wire of the board 110 connecting the resonator 120 and the signal terminals 111A and 111B in FIG. 1 is omitted.

Like the bonding wires 130A and 130B in the filter circuit 40B for comparison illustrated in FIG. 8, the bonding wires 140A and 140B for ground illustrated in FIG. 1 are not provided for the bonding wires 130C and 130D; therefore, a high-frequency signal propagates in a signal transmission path in which the impedance is not matched.

In addition, the end of the bonding wire 130C opposite to the end connected to the resonator 120B is connected to a signal wire 15 via the signal terminal corresponding to the signal terminal 11A or 11B illustrated in FIG. 1. In addition, the end of the bonding wire 130D opposite to the end connected to the resonator 120B is connected to a ground wire of a board corresponding to the board 10 via the ground terminal corresponding to the ground terminal 12A or 12B illustrated in FIG. 1.

### Simulation Results of Filter Circuit 40B for Comparison

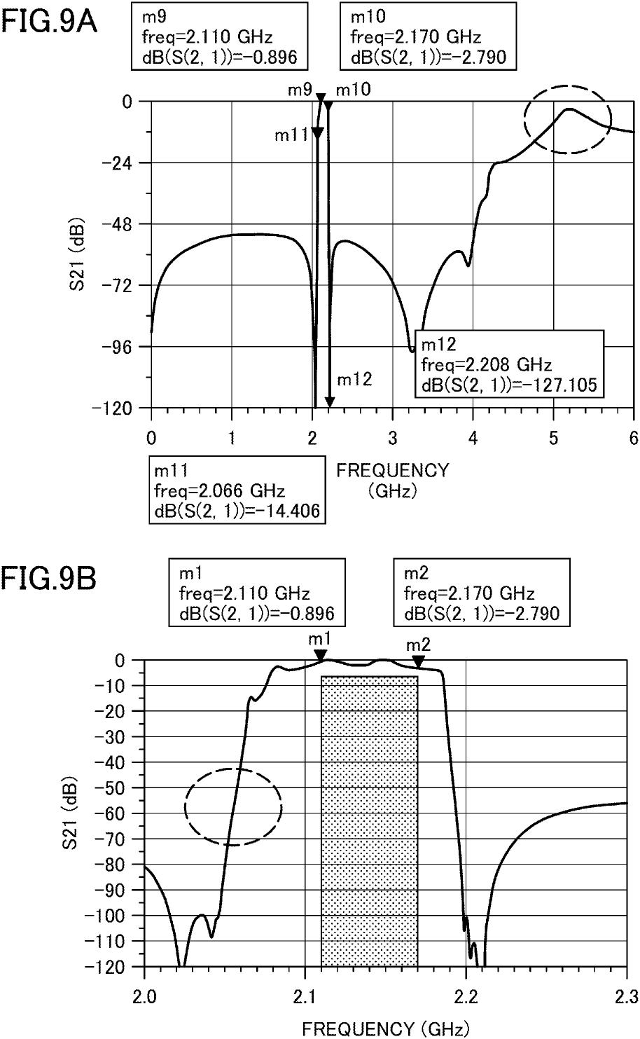

FIGS. 9A and 9B are diagrams illustrating simulation results of the S parameter for the filter circuit 40B for comparison. FIGS. 9A and 9B illustrate an S21 parameter (passing characteristic). FIG. 9B is a diagram illustrating an enlarged view of FIG. 9A in the horizontal (frequency) direction.

As illustrated in FIGS. 9A and 9B, m9 (FIG. 9A) and m1 (FIG. 9B) as the lower limit frequency of the passband were 2.110 GHz, and the S21 parameter was -0.896 dB. In addition, m10 (FIG. 9A) and m2 (FIG. 9B) as the upper limit frequency of the passband were 2.170 GHz, and the S21 parameter was -2.790 dB.

A region illustrated in gray in FIG. 9B, being less than or equal to approximately -2.5 dB between 2.110 GHz and 2.170 GHz is, as in FIG. 7B, is a region where it is desired to be secured as a pass-through characteristic, and as for the characteristic of the S21 parameter, only a small part enters the gray region; however, as indicated in FIG. 9B with a surrounding dashed circle, it could be confirmed that the lower limit frequency of the passband extends to the lower limit frequency side, to be wider than an appropriate passband characteristic. In addition, as indicated in FIG. 9A with a surrounding dashed circle, it could be confirmed that the S21 parameter increased to approximately -5 dB around 5 GHz, and hence, the cutoff characteristic was insufficient.

As described above, in the filter circuit 40B for comparison in which a high-frequency signal propagates on a signal transmission line in which the impedance is not matched, degradation of the signal characteristics (in particular, degradation of the blocking characteristic) could be confirmed.

### Simulation Model of Filter Circuit 200 According to Embodiment

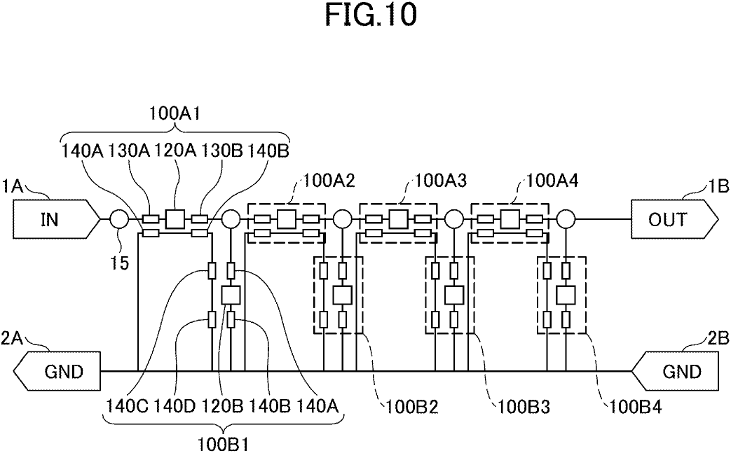

FIG. 10 is a diagram illustrating a simulation model of a filter circuit 200 according to an embodiment. The filter circuit 200 is a ladder type BPF like the filter circuits 40A and 40B for comparison illustrated in FIGS. 6 and 8. Here, for elements that are substantially the same as those of the filter circuits 40A and 40B for comparison illustrated in FIGS. 6 and 8, the same reference numerals are assigned, and the description is omitted.

The filter circuit 200 has a configuration in which bonding wires 140A, 140B, 140C, and 140D for ground are added to the filter circuit 40B illustrated in FIG. 8. Therefore, the filter circuit 200 includes four resonators 120A and four resonators 120B.

Parts including the respective four resonators 120A constitute the filter circuit 100A1 to 100A4. The configuration of each of the filter circuits 100A1 to 100A4 is substantially the same as that of the filter circuit 100 illustrated in FIGS. 1 and 5A. Therefore, the bonding wires 140A and 140B are provided along and close to the bonding wires 130A and 130B, and in the signal transmission lines implemented by the bonding wires 130A and 130B, the impedance is matched. In addition, each of the filter circuits 100A1 to 100A4 includes one board 110.

In addition, parts including the respective four resonators 120B constitute the filter circuit 100B1 to 100B4. The configuration of each of the filter circuits 100B1 to 100B4 is substantially the same as that of the filter circuit 100 illustrated in FIGS. 1 and 5A, and the configuration is substantially the same as that of each of the filter circuits 100A1 to 100A4. In addition, each of the filter circuits 100B1 to 100B4 includes one board 110.

Therefore, the filter circuit 200 illustrated in FIG. 10 includes eight filter circuits 100A1 to 100A4 and 100B1 to 100B4. The filter circuit 200 has a configuration in which the filter circuits 100A1 to 100A4 and 100B1 to 100B4 are connected to signal wires and ground wires of the board 10, respectively, using the bonding wires 130A to 130D and the bonding wires 140A to 140D by arranging eight boards 110 on the board 10 illustrated in FIG. 1. In the filter circuit 200 illustrated in FIG. 10, the signal wires 15 are the signal wires of the board 10.

In each of the filter circuits 100B1 to 100B4, the bonding wires 130C and 130D are connected to both sides of the resonator 120B, like the bonding wires 130A and 130B in each of the filter circuits 100A1 to 100A4. The bonding wire 130C is an example of a third signal wire, and the bonding wire 130D is an example of a fourth signal wire.

In addition, a signal terminal (an example of a third signal terminal) corresponding to the signal terminal 111A illustrated in FIG. 1 is present between the resonator 120B and the bonding wire 130C in practice, and like the bonding wire 130A and the resonator 120 illustrated in FIG. 1, the signal terminal (an example of a third signal terminal) is connected to the terminal of the resonator 120B (an example of a third terminal) via the signal wire of the board 110.

In addition, similarly, a signal terminal (an example of a fourth signal terminal) corresponding to the signal terminal 111B illustrated in FIG. 1 is present between the resonator 120B and the bonding wire 130D in practice, and like the bonding wire 130B and the resonator 120 illustrated in FIG. 1, the signal terminal (an example of a fourth signal terminal) is connected to the terminal of the resonator 120B (an example of a fourth terminal) via the signal wire of the board 110.

In addition, in each of the filter circuits 100B1 to 100B4, the bonding wires 140C and 140D are arranged along and close to the bonding wires 130C and 130D, like the bonding wires 140A and 140B with respect to the bonding wires 130A and 130B in each of the filter circuits 100A1 to 100A4. Therefore, in the signal transmission lines implemented by the bonding wires 130C and 130D, the impedance is matched.

The bonding wires 140C and 140D are examples of a second reference potential wire. The bonding wire 140C is an example of a third portion of a second reference potential wire, and bonding wire 140D is an example of a fourth portion of a second reference potential wire. Note that one bonding wire may be used instead of being divided into two as in the case of the bonding wires 140C and 140D.

As an example, the bonding wires 140A and 140B of the filter circuit 100A1 and the bonding wires 140C and 140D of the filter circuit 100B1 are connected in series to each other in a line branched from a ground wire connecting the ground terminal 2A and the ground terminal 2B and connected in parallel. The same applies to the filter circuit 100A2 and the filter circuit 100B2; the filter circuit 100A3 and the filter circuit 100B3; and the filter circuit 100A4 and the filter circuit 100B4.

### Simulation Results of Filter Circuit 200 According to Embodiment

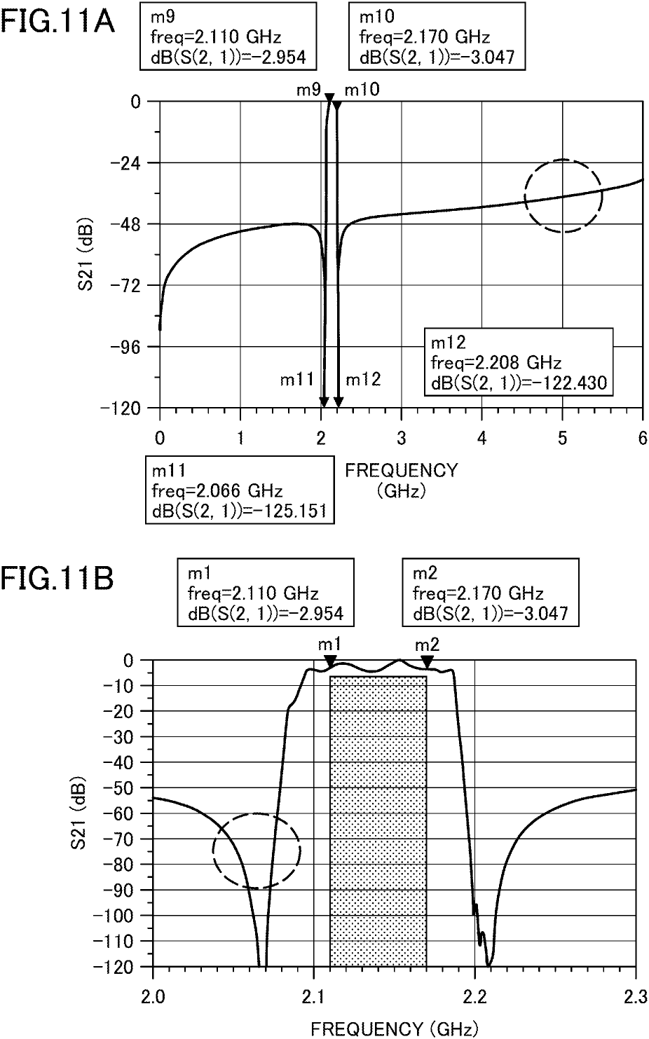

FIGS. 11A and 11B are diagrams illustrating simulation results of the S parameter for a filter circuit 200 according to the embodiment. FIGS. 11A and 11B illustrate an S21 parameter (passing characteristic). FIG. 11B is a diagram illustrating an enlarged view of FIG. 11A in the horizontal (frequency) direction.

As illustrated in FIGS. 11A and 11B, m9 (FIG. 11A) and m1 (FIG. 11B) as the lower limit frequency of the passband were 2.110 GHz, and the S21 parameter was -2.954 dB. In addition, m10 (FIG. 11A) and m2 (FIG. 11B) as the upper limit frequency of the passband were 2.170 GHz, and the S21 parameter was -3.047 dB.

A region illustrated in gray in FIG. 11B, being less than or equal to approximately -2.5 dB between 2.110 GHz and 2.170 GHz is, as in FIG. 7B, is a region where it is desired to be secured as a pass-through characteristic, and as for the characteristic of the S21 parameter, only a small part enters the gray region, and as indicated in FIG. 11B with a surrounding dashed circle, it could be confirmed that the lower limit frequency of the pass band was suppressed from spreading to the lower limit frequency side, and that an appropriate pass characteristic was obtained. In this way, compared with the S21 parameter of the filter circuit 40B for comparison illustrated in FIG. 9A, it could be confirmed that the transmission characteristic of the signal was improved significantly.

In addition, as indicated in FIG. 11A with a surrounding dashed circle, the S21 parameter decreased to approximately -40 dB around 5 GHz, and it could be confirmed that the cutoff characteristic was sufficient. Also in this regard, it could be confirmed that the S21 parameter of the filter circuit 40B for comparison illustrated in FIG. 9A was improved significantly.

### Effects

As described above, in the high-frequency circuit 50A, the bonding wires 140A and 140B are provided along and close to the bonding wires 130A and 130B, and in the signal transmission lines of the bonding wires 130A and 130B for signals, the impedance is matched. The same applies to the high-frequency circuit 50B.

Therefore, the high-frequency circuits 50A and 50B can be provided in which the impedance can be matched with a simple circuit configuration.

In addition, the bonding wires 130A and 130B connected to the resonator 120 having a filter characteristic, and the bonding wires 140A and 140B arranged along and close to the bonding wires 130A and 130B held at the reference potential, are included.

Therefore, the filter circuit 100 can be provided in which the impedance can be matched with a simple circuit configuration.

In addition, the bonding wires arranged along and close to the bonding wires 130A and 130B are separated into the bonding wire 140A corresponding to the bonding wire 130A and the bonding wire 140B corresponding to the bonding wire 130B; therefore, the impedance of the bonding wires 130A and 130B for signals can be matched more securely.

In addition, the filter circuit 200 includes the filter circuit 100A1 to 100A4 having the resonator 120A and the filter circuit 100B1 to 100B4 having the resonator 120B, and the filter circuits 100A1 to 100A4 and 100B1 to 100B4 are connected in a ladder shape. In addition, in the filter circuit 100A1 to 100A4, the bonding wires 140A and 140B are provided along and close to the bonding wires 130A and 130B, and the signal transmission paths of the bonding wires 130A and 130B for signals are matched in impedance. In addition, in the filter circuit 100B1 to 100B4, the bonding wires 140C and 140D are provided along and close to the bonding wires 130C and 130D, and the signal transmission paths of the bonding wires 130C and 130D for signals are matched in impedance.

Therefore, the ladder-type filter circuit 200 can be provided in which the impedance can be matched with a simple circuit configuration.

In addition, the bonding wires arranged along and close to the bonding wires 130C and 130D are separated into the bonding wire 140C corresponding to the bonding wire 130C and the bonding wire 140D corresponding to the bonding wire 130D; therefore, the impedance of the bonding wires 130C and 130D for signals can be matched more securely.

In addition, the resonators 120, 120A, and 120B are BAW filters; therefore, the resonant characteristic of the BAW filter can be utilized to implement a BPF (bandpass filter).

In addition, the passband of the resonator 120A is higher than the passband of the resonator 120B, and the passband of the resonator 120B is lower than the passband of the resonator 120B; therefore, the upper limit frequency and the lower limit frequency of the passband as the BPF of the ladder-type filter circuit 200 can be specified.

Note that as above, the form in which the ladder-type filter circuit 200 includes the four resonators 120A and the four resonators 120B has been described. However, the number of resonators 120A and 120B is not limited to four. As more than one series-arm resonator 120A are required, two or more would be sufficient. In addition, at least one parallel-arm resonator 120B is required, and there may be two or more (a plural number).

### Modified Example

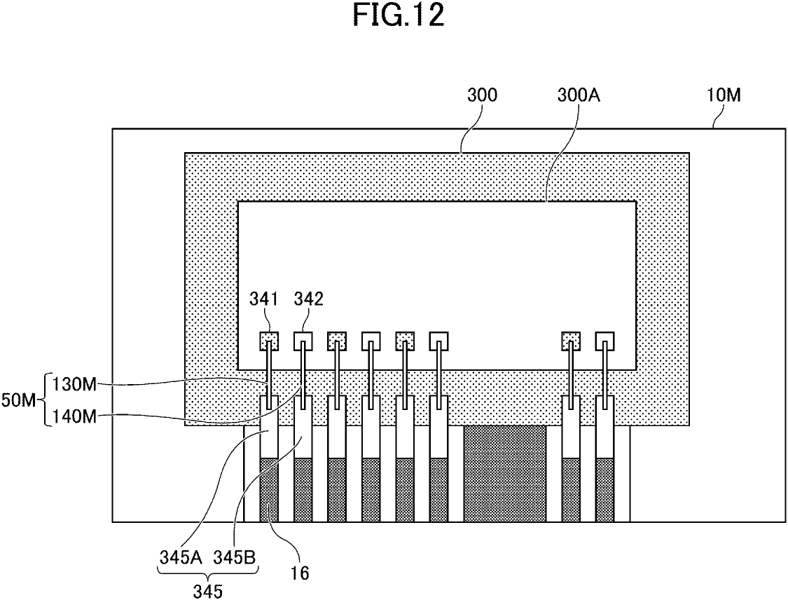

FIG. 12 is a diagram illustrating an IC (Integrated Circuit) package 300 to which a high-frequency circuit 50M of a modified example of the embodiment is applied. The IC package 300 is mounted on the upper surface of a board 10M (the surface illustrated in FIG. 12). The IC package 300 includes an IC chip 300A, and signal terminals 341 and ground terminals 342 are arranged alternately on the upper surface of the IC chip 300A (in the lateral direction in FIG. 12). In addition, the IC package 300 includes lead frames 345 provided around the IC chip 300A. The lead frame 345 has leads 345A and 345B. The lead 345A is a lead for signals and the lead 345B is a lead for ground. The leads 345A and 345B are alternately arranged corresponding to the signal terminals 341 and the ground terminals 342. The leads 345A and 345B are connected to wires 16 provided on the upper surface of the board 10M.

The high-frequency circuit 50M includes bonding wires 130M for signals and bonding wires 140M for ground. The bonding wire 130M for signals connects the signal terminal 341 to the lead 345A, and the bonding wire 140M for ground connects the ground terminal 342 to the lead 345B. The bonding wire 130M constructs the bonding wire 130M to transmit a digital signal between the IC chip 300A and the lead frame 345.

The bonding wire 140M is provided along and close to the bonding wire 130M. Therefore, in the signal transmission lines implemented by the bonding wire 130M between the signal terminal 341 and the lead 345A, the impedance is matched. In addition, a return path is formed between the ground terminal 342 and the lead 345B by being connected by the bonding wire 140M.

Therefore, the high-frequency circuit 50M can be provided in which the impedance can be matched with a simple circuit configuration, and digital signals can be transmitted.

As above, the radio-frequency circuit and the filter circuit according to the illustrative embodiments in the present disclosure have been described; note that the present disclosure is not limited to the specifically disclosed embodiments and various modifications and alterations can be made without departing from the scope of the claims.

What is claimed is:

1. A high-frequency circuit comprising:
a signal wire connecting a pair of signal terminals; and
a reference potential wire arranged along and close to the signal wire and connecting a pair of reference potential terminals.

2. The high-frequency circuit as claimed in claim 1, wherein the pair of signal terminals are terminals to transmit an analog signal or a digital signal.

3. A filter circuit comprising:
a first resonator having a filter characteristic;
a first signal terminal connected to a first terminal of the first resonator;
a first signal wire connected to the first signal terminal;
a second signal terminal connected to a second terminal of the first resonator;
a second signal wire connected to the second signal terminal; and
a first reference potential wire arranged along and close to the first signal wire and the second signal wire, and held at a reference potential.

4. The filter circuit as claimed in claim 3, wherein the first reference potential wire includes a first portion arranged along and close to the first signal wire, and a second portion arranged along and close to the second signal wire.

5. The filter circuit as claimed in claim 3, further comprising:
a signal input terminal and a signal output terminal;
one or more second resonators each having a filter characteristic;
one or more third signal terminals connected to third terminals of the one or more second resonators;
one or more third signal wires connected to the one or more third signal terminals;
one or more fourth signal terminals connected to fourth terminals of the one or more second resonators;
one or more fourth signal wires connected to the one or more fourth signal terminals;
one or more second reference potential wires arranged along and close to the one or more third signal wires and the one or more fourth signal wires, and held at the reference potential; and
a plurality of instances of the first resonator, a plurality of instances of the first signal wire, and a plurality of instances of the second signal wire,
wherein the plurality of instances of the first resonator, the plurality of instances of the first signal wires, the plurality of instances of the second signal wire, the one or more second resonators, the one or more third signal wires, and the one or more fourth signal wires are connected in a ladder shape among the signal input terminal, the signal output terminal, and the reference potential point.

6. The filter circuit as claimed in claim 5, wherein the second reference potential wire includes a third portion arranged along and close to the third signal wire, and a fourth portion arranged along and close to the fourth signal wire.

7. The filter circuit as claimed in claim 5, wherein the first resonator and the second resonator are BAW (Bulk Acoustic Wave) filters.

8. The filter circuit as claimed in claim 5, wherein a first passband of the first resonator is higher than a second passband of the second resonator.
